(19) United States
(12) Patent Application Publication
(10) Pub. No.: US 2015/0060966 A1
(43) Pub. Date: Mar. 5, 2015

(54) IMAGE SENSORS WITH SILICIDE LIGHT SHIELDS

(71) Applicant: Aptina Imaging Corporation, George Town (KY)

(72) Inventors: Victor Lenchenkov, Sunnyvale, CA (US); Hirofumi Komori, San Jose, CA (US)

(21) Appl. No.: 14/464,408

(22) Filed: Aug. 20, 2014

Related U.S. Application Data
(60) Provisional application No. 61/870,423, filed on Aug. 27, 2013.

(51) Int. Cl. H01L 27/146

(52) U.S. Cl. CPC H01L 27/14643; H01L 27/14623; H01L 27/14636; H01L 27/14689; H01L 27/14685; H01L 27/14629
USPC 257/292; 438/59

(57) ABSTRACT

An image sensor with an array of image sensor pixels is provided. Each image pixel may include a photodiode and associated pixel circuits formed in a semiconductor substrate. Buried light shielding structures may be formed on the substrate to prevent pixel circuitry that is formed in the substrate between two adjacent photodiodes from being exposed to incoming light. The buried light shields may be formed over conductive gate structures. A metal silicide layer may be formed to completely cover these conductive gate structures. Antireflective coating material may optionally be formed over the metal silicide layer. Forming gate structures with a metal silicide liner can help reduce optical pixel crosstalk and enhance global shutter efficiency.

This application claims the benefit of provisional patent application No. 61/870,423, filed Aug. 27, 2013, which is hereby incorporated by reference herein in its entirety.

### BACKGROUND

This relates generally to image sensors, and more specifically, to image sensors with buried light shields.

Image sensors are commonly used in electronic devices such as cellular telephones, cameras, and computers to capture images. Conventional image sensors are fabricated on a semiconductor substrate using complementary metal-oxide-semiconductor (CMOS) technology or charge-coupled device (CCD) technology. The image sensors may include an array of image sensor pixels each of which includes a photodiode and other operational circuitry such as transistors formed in the substrate.

A dielectric stack is formed on the substrate over the photodiodes. The dielectric stack includes metal routing lines and metal vias formed in dielectric material. Light guides are often formed in the dielectric stack to guide the trajectory of incoming light. A color filter array is typically formed over the dielectric stack to provide each pixel with sensitivity to a certain range of wavelengths. Microlenses are formed over the color filter array. Light enters the microlenses and travels through the color filters into the dielectric stack.

In a conventional image sensor configured to operate in global shutter mode, each image sensor pixel includes a photodiode for detecting incoming light and a separate storage diode for temporarily storing charge. The storage diode should not be exposed to incoming light. In such arrangements, structures such as tungsten buried light shields (abbreviated as WBLS) are formed on the substrate between neighboring photodiodes to help prevent stray light from affecting the storage diode. At least some metal vias are formed through gaps in the buried light shields in order to control pixel transistors formed between two adjacent photodiodes. Shielding storage diodes in this way can help reduce crosstalk and increase global shutter efficiency (i.e., the buried light shields are designed to prevent stray light from entering regions of the substrate located between two adjacent photodiodes).

In practice, however, the tungsten buried light shield reflects stray light. The reflected stray light may then strike nearby metal routing structures and be scattered back towards the substrate, through the existing gaps in the buried light shield, and corrupt the storage diode. This results in undesirable pixel crosstalk and degraded global shutter efficiency.

It would therefore be desirable to be able to provide image sensors with improved inter-pixel shielding arrangements.

### BRIEF DESCRIPTION OF THE DRAWINGS

FIG. 1 is a diagram of an illustrative electronic device in accordance with an embodiment of the present invention.

FIG. 2 is a diagram of an illustrative image sensor pixel that may be used to support global shutter operation in accordance with an embodiment of the present invention.

FIG. 3 is a cross-sectional side view of a conventional image sensor with reflective buried light shields.

FIG. 4 is a cross-sectional side view of an illustrative image sensor with a silicide liner formed on polysilicon gate structures in accordance with an embodiment of the present invention.

FIG. 5 is a cross-sectional side view showing how polysilicon gate structures may be used to define the aperture ratio of an image sensor pixel in accordance with an embodiment of the present invention.

FIG. 6 is a flowchart of illustrative steps involved in forming a silicide liner over polysilicon gate structures in accordance with an embodiment of the present invention.

FIG. 7 is a block diagram of a processor system that may employ some of the embodiments of FIGS. 4-6 in accordance with an embodiment of the present invention.

### DETAILED DESCRIPTION

Embodiments of the present invention relate to image sensors, and more particularly, to image sensors with buried light shield structures with antireflective coating. It will be recognized by one skilled in the art, that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices include image sensors that gather incoming light to capture an image. The image sensors may include arrays of imaging pixels. The pixels in the image sensors may include photosensitive elements such as photodiodes that convert the incoming light into image signals. Image sensors may have any number of pixels (e.g., hundreds or thousands of pixels or more). A typical image sensor may, for example, have hundreds of thousands or millions of pixels (e.g., megapixels). Image sensors may include control circuitry such as circuitry for operating the imaging pixels and readout circuitry for reading out image signals corresponding to the electric charge generated by the photosensitive elements.

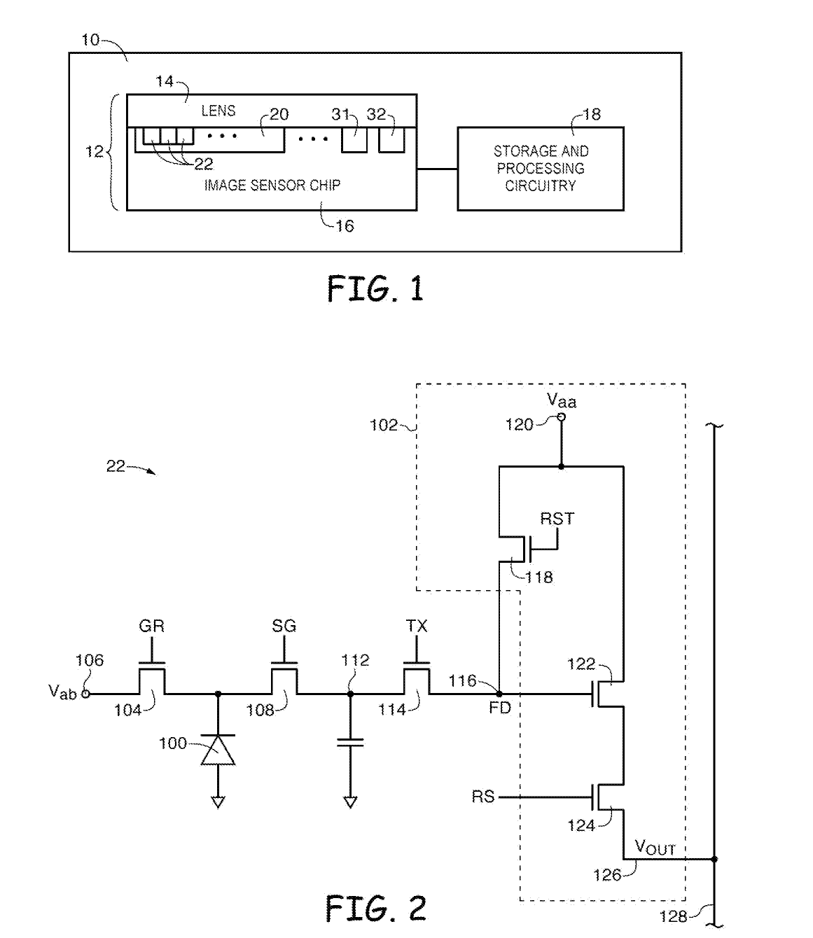

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include one or more lenses 14 and one or more corresponding image sensors 16. Image sensor 16 may be an image sensor system-on-chip (SOC) having additional processing and control circuitry such as analog control circuitry 31 and digital control circuitry 32 on a common image sensor integrated circuit die with image pixel array 20 or on a separate companion die/chip.

During image capture operations, light from a scene may be focused onto an image pixel array (e.g., array 20 of image pixels 22) by lens 14. Image sensor 16 provides corresponding digital image data to analog circuitry 31. Analog circuitry 31 may provide processed image data to digital circuitry 32 for further processing. Circuitry 31 and/or 32 may also be used in controlling the operation of image sensor 16. Image sensor 16 may, for example, be a backside illumination image sensor. If desired, camera module 12 may be provided with an array of lenses 14 and an array of corresponding image sensors 16.

Device 10 may include additional control circuitry such as storage and processing circuitry 18. Circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be further processed and/or stored using processing circuitry 18. Processed image data may, if desired, be provided to external equipment (e.g., a computer or other device) using wired and/or wireless communications paths coupled to processing circuitry 18. Processing circuitry 18 may be used in controlling the operation of image sensors 16.

Image sensors 16 may include one or more arrays 20 of image pixels 22. Image pixels 22 may be formed in a semiconductor substrate using complementary metal-oxide-semiconductor (CMOS) technology or charge-coupled device (CCD) technology or any other suitable photosensitive devices.

Embodiments of the present invention relate to image sensor pixels configured to support global shutter operation. For example, the image pixels may each include a photodiode, floating diffusion region, and a local storage region. With a global shutter scheme, all of the pixels in an image sensor are reset simultaneously. The transfer operation is then used to simultaneously transfer the charge collected in the photodiode of each image pixel to the associated storage region. Data from each storage region may then be read out on a per-row basis.

FIG. 2 is a circuit diagram of an illustrative image sensor pixel 22 operable in global shutter mode. As shown in FIG. 2, pixel 22 may include a photosensitive element such as photodiode 100. A first (positive) power supply voltage Vaa may be supplied at positive power supply terminal 120. A second power supply voltage Vab may be supplied at second power supply terminal 106. Incoming light may be collected by photodiode 100. Photodiode 100 may then generate charge (e.g., electrons) in response to receiving impinging photons. The amount of charge that is collected by photodiode 100 may depend on the intensity of the impinging light and the exposure duration (or integration time).

Before an image is acquired, reset control signal RST may be asserted. Asserting signal RST turns on reset transistor 118 and resets charge storage node 116 (also referred to as floating diffusion region FD) to Vaa. Reset control signal RST may then be deasserted to turn off reset transistor 118. Similarly, prior to charge integration, a global reset signal GR may be pulsed high to reset photodiode 100 to power supply voltage Vab (e.g., by passing Vab to photodiode 100 through global reset transistor 104).

Pixel 22 may further include a storage transistor 108 operable to transfer charge from photodiode 100 to storage node (sometimes called a charge storage region or storage region) 112. Charge storage region 112 may be a doped semiconductor region (e.g., a doped silicon region formed in a silicon substrate by ion implantation, impurity diffusion, or other doping techniques) that is capable of temporarily storing charge transferred from photodiode 100. Region 112 that is capable of temporarily storing transferred charge is sometimes referred to as a “storage diode” (SD).

Pixel 22 may include a transfer gate (transistor) 114. Transfer gate 114 may have a gate terminal that is controlled by transfer control signal TX. Transfer signal TX may be pulsed high to transfer charge from storage diode region 112 to charge storage region 116 (sometimes called a floating diffusion region). Floating diffusion (FD) region 116 may be a doped semiconductor region (e.g., a region in a silicon substrate that is doped by ion implantation, impurity diffusion, or other doping processes). Floating diffusion region 116 may serve as another storage region for storing charge during image data gathering operations.

Pixel 22 may also include readout circuitry such as charge readout circuit 102. Charge readout circuit 102 may include row-select transistor 124 and source-follower transistor 122. Transistor 124 may have a gate that is controlled by row select signal RS. When signal RS is asserted, transistor 124 is turned on and a corresponding signal Vout (e.g. an output signal having a magnitude that is proportional to the amount of charge at floating diffusion node 116), is passed onto output path 128.

Image pixel array 20 may include pixels 22 arranged in rows and columns. A column readout path such as output line 128 may be associated with each column of pixels (e.g., each image pixel 22 in a column may be coupled to output line 128 through respective row-select transistors 124). Signal RS may be asserted to read out signal Vout from a selected image pixel onto column readout path 124. Image data Vout may be fed to processing circuitry 18 for further processing. The circuitry of FIG. 2 is merely illustrative. If desired, pixel 22 may include other pixel circuitry.

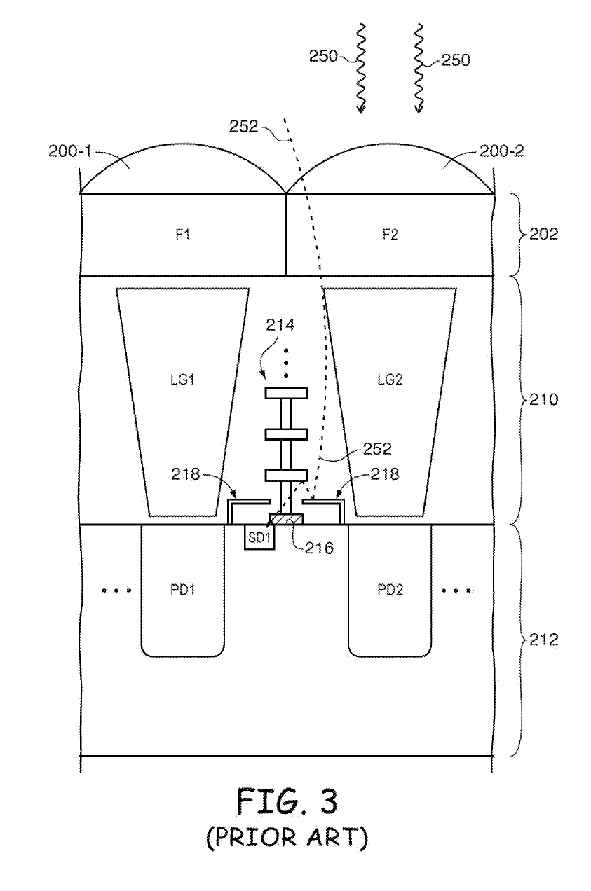

FIG. 3 is a cross-sectional side view showing two adjacent conventional image sensor pixels operable in global shutter mode. As shown in FIG. 3, photodiode PD1 that is part of a first image sensor pixel and photodiode PD2 that is part of a second image sensor pixel are formed in a p-type substrate 212. Circuitry such as a storage diode SD1 and a storage gate conductor 216 (i.e., a gate conductor of the storage transistor) that is associated with the first image pixel may be formed on substrate 212 between photodiodes PD1 and PD2.

A dielectric stack 210 is formed on substrate 212. A first light guide LG1 for directing incoming light towards PD1 is formed above PD1 in dielectric stack 210. A second light guide LG2 for directing incoming light towards PD2 is formed above PD2 in dielectric stack 210. Metal interconnect routing paths 214 are formed in dielectric stack 210 between light guides LG1 and LG2. At least some metal routing path makes contact with storage gate conductor 216 for controlling the storage transistor.

A color filter array 202 is formed over dielectric stack 210. In particular, a first color filter element F1 is formed on stack 210 directly above PD1, whereas a second color filter element F2 is formed on stack 210 directly above PD2. First filter element F1 may be configured to pass green light, whereas second filter element F2 may be configured to pass red light. A first microlens 200-1 that is configured to focus light towards PD1 can be formed on first filter element F1, whereas a second microlens 200-2 that is configured to focus light towards PD2 can be formed on second filter element F2.

Ideally, incoming light 250 enters microlenses 200-1 and 200-2 from above and is directed towards the corresponding photodiodes. For example, light entering microlens 200-1 should be directed towards PD1, whereas light entering microlens 200-2 should be directed towards PD2. In practice, however, stray light may potentially strike regions on substrate 212 between adjacent photodiodes and result in undesired crosstalk and reduction in global shutter efficiency (i.e., stray light may undesirably affect the amount of charge in storage diode region SD1). Regions on substrate 212 where light should not be allowed to strike may be referred to as “dark” regions.

In an effort to prevent stray light from entering the dark regions, tungsten buried light shields 218 are formed to partially cover the dark regions (i.e., light shields 218 are designed to shield SD1 and storage gate 216). There may be gaps in the buried light shields through which interconnects 214 are formed to make contact with circuitry in the dark regions. These gaps are therefore sometimes referred to as a “buried light shield contact window.”

Tungsten buried light shields 218 are reflective. In practice, stray light may reflect off the tungsten buried light shields 218; the reflected light may strike nearby interconnect routing structures 214 and be scattered through the gaps in the light shields into the dark regions (as indicated by path 252). Even though the tungsten buried light shields help to reduce crosstalk, stray light can still be inadvertently scattered into the dark regions on substrate 212. It may therefore be desirable to provide improved ways for shielding the dark regions.

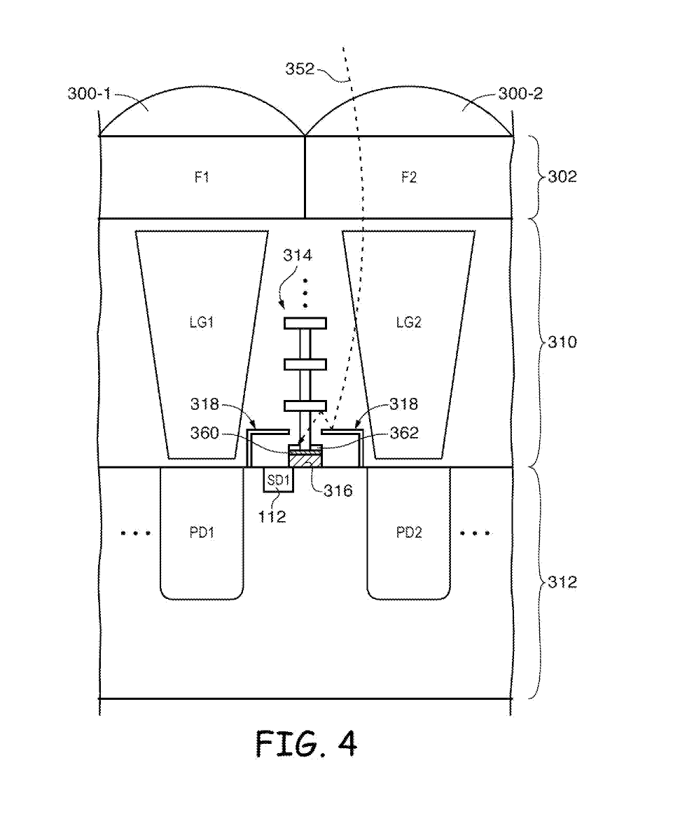

In accordance with an embodiment of the present invention, image sensor pixels may be provided with a silicide layer formed on top of conductive gate structures. FIG. 4 shows two adjacent image pixels in array 20. As shown in FIG. 4, a first photosensitive element such as photodiode PD1 that is associated with a first image sensor pixel 22 and a second photosensitive element such as photodiode PD2 that is associated with a second image sensor pixel 22 may be formed in a semiconductor substrate such as substrate 312 (e.g., a p-type semiconductor substrate). Pixel circuitry such as storage diode SD1, storage gate conductor 316 (e.g., a gate conductor associated with storage transistor 108 or other control transistor in pixel 22), floating diffusion region FD, and other pixel structures may be formed in a region of substrate 312 between PD1 and PD2.

A dielectric stack such as dielectric stack 310 may be formed on substrate 312. Dielectric stack 310 may be formed from dielectric material such as silicon oxide. A first light guide LG1 that is used to direct light toward PD1 may be formed in dielectric stack 310 above PD1. A second light guide LG2 that is used to direct light toward PD2 may be formed in dielectric stack 310 above PD2. Interconnect routing structures 314 (e.g., conductive signal routing paths and conductive vias) may be formed in dielectric stack 310 between light guides LG1 and LG2. Dielectric stack 310 may therefore sometimes be referred to as an interconnect stack. In general, dielectric stack 310 may include alternating metal routing layers (e.g., dielectric layers in which metal routing paths are formed) and via layers (e.g., dielectric layers in which conductive vias coupling conductive structures from one adjacent metal routing layer to corresponding conductive structures in another adjacent metal routing layer).

A color filter array such as color filter array structure 302 may be formed on top of dielectric stack 310. In the example of FIG. 4, a first color filter element F1 may be formed on stack 310 above LG1, and a second color filter element F2 may be formed on stack 310 above LG2. Light guide structures such as LG1 and LG2 need not be used. Color filter element F1 may serve to pass light in a first portion of the visible spectrum, whereas color filter element F2 may serve to pass light in a second portion of the visible spectrum that is different than the first portion. Color filter elements F1 and F2 may each be configured to pass through a selected one of: green light, red light, blue light, cyan light, magenta light, yellow light, and/or other types of light.

A microlens array may be formed on top of color filter array 302. The microlens array may include a first microlens 300-1 formed on top of first color filter element F1 and a second microlens 300-2 formed on top of second color filter element F2. Microlens 300-1 may be used to focus light towards PD1, whereas microlens 300-2 may be used to focus light towards PD2.

Light shielding structures such as buried light shielding (BLS) structures 318 may be formed on substrate 312 to prevent stray light from entering regions on substrate 312 located between adjacent photodiodes (e.g., structures 318 may be configured to prevent pixel structures such as storage diode region 112 from being exposed to incoming light). Buried light shielding structures 318 may be formed from tungsten, copper, gold, silver, aluminum, or other suitable conductive material.

As described above in connection with FIG. 3, buried light shielding structures 318 by themselves are sometimes not entirely sufficient to prevent stray light from entering undesired regions of the substrate. In accordance with an embodiment, a silicide layer such as silicide layer 360 may be completely formed over the storage gate conductor 316. As shown in FIG. 4, silicide layer 360 may be formed across the entire length and width and directly on the top surface of the polysilicon gate material of the storage transistor. Formed in this way, silicide layer 360 may serve as an ohmic contact for the metal interconnect routing structures 314 and for absorbing stray light 352 that has not yet been blocked by the buried light shields 318 (e.g., for absorbing light that has leaked through the buried light shield contact window). Silicide layer 360 formed in this way may sometimes be referred to as a silicide light shield.

For example, a thin layer of metal silicide (e.g., a metal silicide liner that is 5-50 nanometers [nm] thick) may be formed either as metal directly on the polysilicon or as a co-spattered alloy. Metal silicides generally exhibit relatively high conductivity compared to tungsten and good absorptive optical properties for absorbing light in the 400-700 nanometer spectral range. Examples of metal silicides that can be used may include tungsten silicide (WSi₂), titanium silicide (TiSi₂), tantalum silicide (TaSi₂), nickel silicide (NiSi₂), molybdenum silicide (MoSi₂), Hafnium silicide (HfSi₂), cobalt silicide (CoSi), palladium silicide (Pd₂Si), platinum silicide (PtSi), magnesium silicide (Mg₂Si), a combination of these materials, and/or other suitable metal silicide materials.

In the example of FIG. 4, metal silicide liner 360 is used in conjunction with the buried light shielding structures 318 to help improve global shutter efficiency. If desired, the formation of silicide layer 360 on top of gate conductor 316 may serve as an alternative to the buried light shielding structures 318 in smaller pixel configurations in which buried light shields cannot be formed. Because silicide layer 360 is formed directly on the polysilicon gate structures, silicide layer 360 is formed closer to the surface of substrate 312 compared to buried light shielding structures 318 (which are formed in metal routing layers in the dielectric stack that are typically above the polysilicon gate structures). For example, metal silicide layer 360 may be formed at a height of 85 nm from the surface of substrate 312, whereas buried light shields 318 may be formed at a stack height of 350 nm from the surface of the substrate 312. The lower stack height placement of the metal silicide layer generally offers better protection from light incident at non-zero angles (which is typical of scattered and stray light).

If desired, a layer of antireflective coating (ARC) material 362 may be formed on top of silicide layer 360 to help minimize any reflection off the surface of gate conductor 316. The formation of ARC liner 362 can therefore help to further reduce optical pixel crosstalk and increasing global shutter efficiency. Liners 360 and 362 formed in this way can sometimes be referred to collectively as an absorptive antireflective layer.

In accordance with another embodiment, metal silicide material may be formed on not only the gate conductor of the storage transistor but also on any gate structure within an image sensor pixel. Conductive gate structures on which metal silicide can be formed can be either active gate structures associated with any one of the transistors in the pixel (see, pixel 22 of FIG. 2) or “dummy” gate structures that are not actually part of a transistor and/or are not actively driven to any voltage level. The conductive gate structures may generally be formed adjacent to one or more diffusion regions in the substrate.

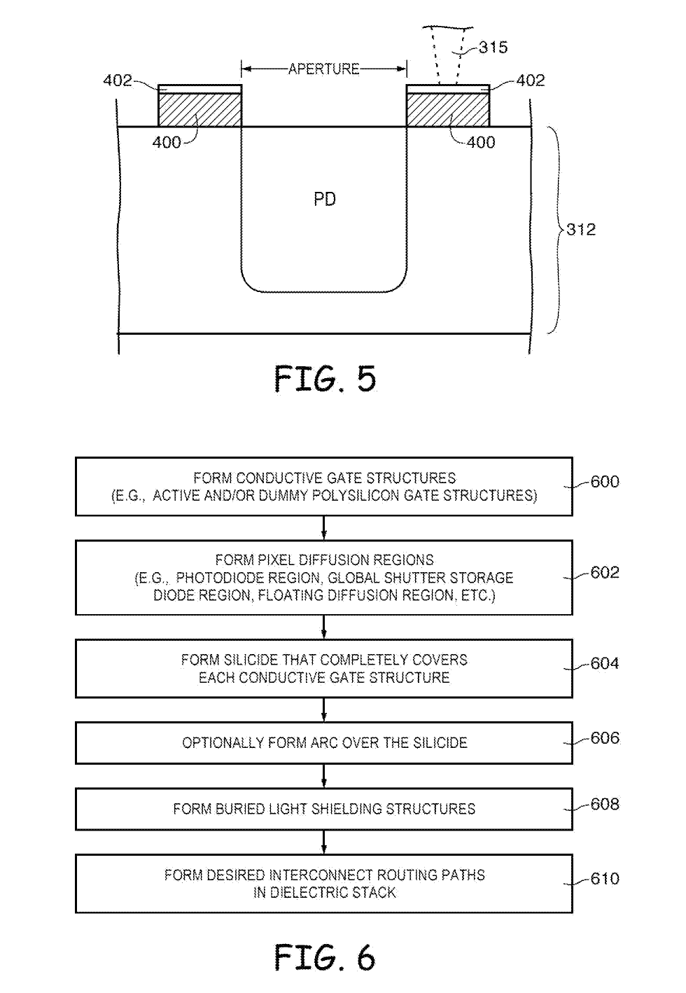

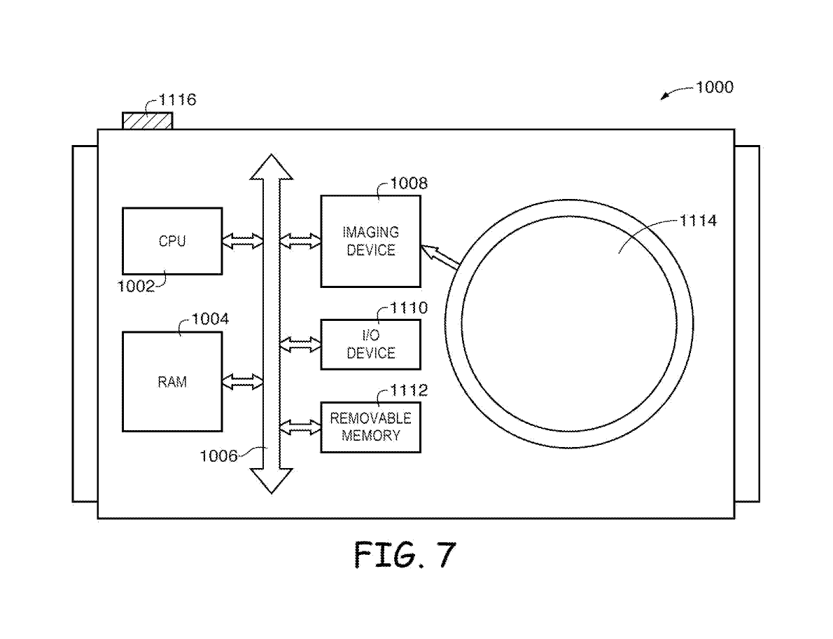

FIG. 5 shows an example in which metal silicide 402 is formed over gate structures 400 that are surrounding a photodiode PD. Gate structures 400 may be either active gate structures or dummy gate structures. In the case of an active gate structure, gate 400 may be coupled to other metal routing paths using conductive via 315 (as an example). In the case of an inactive dummy gate structure, gate 400 need not be coupled to other metal routing paths. In general, portions of substrate 312 that are not occupied by a photodiode or other active transistor diffusion regions can be covered with a gate structure lined with metal silicide material to help reduce pixel crosstalk and enhance global shutter efficiency.

FIG. 6 is a flow chart of illustrative steps involved in forming the pixel structure of FIG. 4. At step 600, conductive gate structures (e.g., active polysilicon gate structures and/or dummy polysilicon gate structures) may be formed on a semiconductor substrate. At step 602, diffusion regions such as photodiode diffusion regions, global shutter storage diode regions, floating diffusion regions, and other active doped regions may be formed in the semiconductor substrate.

At step 604, a layer of metal silicide may be formed to at least completely cover the storage gate transistor of each pixel. If desired, the metal silicide layer may completely cover every conductive gate structure within the image sensor to help absorb unwanted stray light near the surface of the semiconductor substrate. At step 606, anti-reflective coating material may optionally be formed over the metal silicide layer to further help reduce unwanted reflections of the conductive gate structures.

At step 608, buried light shielding structures (e.g., tungsten buried light shields) may then be formed over at least some of the conductive gate structures. At step 610, a dielectric stack having interconnect routing structures can then be formed over the buried light shielding structures. Buried light shields can sometimes be considered as being formed at the bottom layer of the dielectric stack. The buried light shields may have window openings through which the interconnect routing structures can penetrate to make contact with the silicided gate conductors lying beneath the buried light shielding structures.

Other pixel structures such as a color filter array and a microlens array may subsequently be formed over the dielectric stack. Although the methods of operations were described in a specific order, it should be understood that other operations may be performed in between described operations, described operations may be adjusted so that they occur at slightly different times or described operations may be distributed in a system which allows occurrence of the processing operations at various intervals associated with the processing, as long as the processing of the overlay operations are performed in a desired way.

The embodiment described thus far relates to image sensors operating in global shutter mode. If desired, the embodiments of the present invention can also be applied to image sensors operating in rolling shutter mode to help reduce optical pixel cross-talk.

FIG. 11 is a simplified diagram of an illustrative processor system 1000, such as a digital camera, which includes an imaging device 1008 (e.g., the camera module of FIG. 1) employing an imager having pixels with silicide light shields as described above. Without being limiting, such a system could include a computer system, still or video camera system, scanner, machine vision system, vehicle navigation system, video phone, surveillance system, auto focus system, star tracker system, motion detection system, image stabilization system, and other systems employing an imaging device.

Processor system 1000, for example a digital still or video camera system, generally includes a lens 1114 for focusing an image onto one or more pixel array in imaging device 1008 when a shutter release button 1116 is pressed and a central processing unit (CPU) 1002 such as a microprocessor which controls camera and one or more image flow functions. Processing unit 1102 can communicate with one or more input-output (I/O) devices 1110 over a system bus 1006. Imaging device 1008 may also communicate with CPU 1002 over bus 1006. System 1000 may also include random access memory (RAM) 1004 and can optionally include removable memory 1112, such as flash memory, which can also communicate with CPU 1002 over the bus 1006. Imaging device 1008 may be combined with the CPU, with or without memory storage on a single integrated circuit or on a different chip. Although bus 1006 is illustrated as a single bus, it may be one or more busses, bridges or other communication paths used to interconnect system components of system 1000.

Various embodiments have been described illustrating imaging systems with buried light shield structures. A system may include an image sensor module with an array of image sensor pixels and one or more lenses that focus light onto the array of image sensor pixels (e.g., image pixels arranged in rows and columns).

In accordance with an embodiment, an image sensor pixel may include at least a photodiode formed in a semiconductor substrate, a storage diode formed in the substrate, a floating diffusion region formed in the substrate, a storage transistor coupled between the photodiode and the storage diode, a charge transfer transistor coupled between the storage diode and the floating diffusion region, a reset transistor, a source follower transistor, and a row select transistor. At least some of these transistors may have a conductive gate structure on which a metal silicide layer is formed. The metal silicide layer may completely cover the top surface of the conductive gate structure and may help prevent stray light from reaching undesired portions of the substrate. If desired, antireflective coating material may optionally be formed on the metal silicide.

The conductive gate structure may be an active gate conductor for a transistor such as the storage transistor or may be a dummy gate conductor that is not actively driven to any voltage level and that is not coupled to any conductive via. Buried light shielding structures such as tungsten light shields may be formed over the silicided gate structure. A dielectric stack may be formed on the substrate. The dielectric stack may include interconnect routing structures at least some of which are coupled to the silicided gate structure through a gap/window in the buried light shields. In yet other embodiments, a metal silicide liner may be formed on gate structures with the shape of a donut having a hole that defines an aperture through which light can travel to the photodiode. Arranged in this way, the metal silicide layer (along with the buried light shielding structures) can help reduce pixel cross and improve global shutter efficiency.

The foregoing is merely illustrative of the principles of this invention and various modifications can be made by those skilled in the art without departing from the scope and spirit of the invention. The foregoing embodiments may be implemented individually or in any combination.

What is claimed is:

1. An image sensor, comprising:
a semiconductor substrate;
a photosensitive element formed in the semiconductor substrate;
a conductive gate structure formed on the semiconductor substrate; and
a silicide layer formed on the conductive gate structure, wherein the silicide layer completely covers the conductive gate structure and prevents stray light from reaching undesired portions of the semiconductor substrate.

2. The image sensor defined in claim 1, wherein the conductive gate structure comprises a polysilicon gate structure.

3. The image sensor defined in claim 1, wherein the conductive gate structure comprises an active gate structure that is part of a transistor.

4. The image sensor defined in claim 1, wherein the conductive gate structure comprises a dummy gate structure that is not actively driven to any voltage level.

5. The image sensor defined in claim 1, further comprising:
buried light shielding structures formed over the conductive gate structure.

6. The image sensor defined in claim 1, further comprising:
a dielectric stack formed over the semiconductor substrate; and
interconnect routing structures formed in the dielectric stack, wherein the interconnect routing structures are coupled to the conductive gate structure via a window in the buried light shielding structures.

7. The image sensor defined in claim 1, further comprising:
an antireflective coating liner formed on the silicide layer.

8. The image sensor defined in claim 1, wherein the conductive gate is formed in the shape of a donut having a hole through which light can travel to the photosensitive element.

9. The image sensor defined in claim 1, further comprising:
a storage diode region formed in the semiconductor substrate;
a floating diffusion region formed in the semiconductor substrate;
a first transistor that is coupled between the photosensitive element and the storage diode region, wherein the conductive gate structure receives a control signal for turning on and for turning off the first transistor; and
a second transistor that is coupled between the storage diode region and the floating diffusion region.

10. A method of manufacturing an image sensor, comprising:
forming a diffusion region in a semiconductor substrate;
forming a conductive structure on the semiconductor substrate adjacent to the diffusion region, wherein the conductive structure has a top surface; and
forming a layer of metal silicide on the conductive structure, wherein the layer of metal silicide completely covers the top surface of the conductive structure.

11. The method defined in claim 10, wherein forming the conductive structure comprises forming an active gate conductor that serves as part of a transistor.

12. The method defined in claim 10, wherein forming the conductive structure comprises forming a dummy gate conductor that is not coupled to a conductive via.

13. The method defined in claim 10, further comprising
forming antireflective coating material on the layer of metal silicide.

14. The method defined in claim 10, further comprising:
forming light shielding structures that at least partially surround the conductive structure.

15. The method defined in claim 14, further comprising:
forming a dielectric stack over the semiconductor substrate; and
forming interconnect routing structures in the dielectric stack, wherein the interconnect routing structures are coupled to the conductive structure by a via formed through a gap in the light shielding structures.

16. A system, comprising:
a central processing unit;
memory;
a lens;
input-output circuitry; and
an imaging device, wherein the imaging device comprises:
a substrate;
a gate structure formed on the substrate; and
a metal silicide liner that completely covers the gate structure.

17. The system defined in claim 16, wherein the imaging device further comprises:
antireflective coating material formed on the metal silicide liner.

18. The system defined in claim 16, wherein the imaging device further comprises:
a photodiode formed in the substrate;
a storage diode formed in the substrate;
a floating diffusion region formed in the substrate;
a first transistor coupled between the photodiode and the storage diode, wherein the gate structure serves as a gate terminal for the first transistor; and
a second transistor coupled between the storage diode and the floating diffusion region.

19. The system defined in claim 16, wherein the imaging device further comprises:
a tungsten light shield formed over gate structure; and
interconnect routing structures formed over the tungsten light shield, wherein the interconnect routing structures are coupled to the gate structure through a gap in the tungsten light shield.

20. The system defined in claim 16, wherein the gate structure is formed in a donut shape having a hole that defines an aperture through which light can travel to the photodiode.
